(19) United States
(12) Patent Application Publication
(10) Pub. No.: US 2025/0320406 A1
(43) Pub. Date: Oct. 16, 2025

(54) QUANTUM DOT MATERIAL, METHOD FOR PREPARING THE SAME, AND QUANTUM DOT FILM AND BACKLIGHT MODULE USING THE SAME

(71) Applicants: Foxconn Technology Co., LTD, New Taipei (TW); National Taipei University of Technology, Taipei (TW)

(72) Inventors: Chun-Che LIN, Yilan County (TW); Dong-Lin CAI, New Taipei (TW); Ling-Hsuan CHUNG, Changhua City (TW); Po-Chun LI, Taipei (TW); Jung-An CHENG, Miaoli County (TW); Chin-Yueh LIAO, Taipei (TW)

(21) Appl. No.: 19/175,023

(22) Filed: Apr. 10, 2025

(30) Foreign Application Priority Data
Apr. 11, 2024 (CN) 202410434864.8
Aug. 16, 2024 (CN) 202411131560.0

(51) Int. Cl. C09K 11/02; C09K 11/06; G02F 1/13357

(52) U.S. Cl. CPC C09K 11/025; C09K 11/06; C09K 2211/188; G02F 1/133606

(57) ABSTRACT

A quantum dot material includes a core layer, a ligand layer, and a coating layer. The ligand layer is formed to cover at least part of the surface of the core layer, and forms a bond with the core layer. The coating layer is formed to cover at least part of the surface of the ligand layer, and forms a bond with the ligand layer. The ligand layer is formed from at least three ligand compounds, including a first type of ligand compound and a second type of ligand compound. The first type of ligand compound has a first coordinating group for forming a bond with the core layer. The second type of ligand compound has a second coordinating group for forming a bond with the coating layer. The core layer has a crystal structure of ABX₃.

### CLAIM OF PRIORITY AND INCORPORATION BY REFERENCE

The present application claims the priority of the Chinese invention application with an application number of 202410434864.8 filed on Apr. 11, 2024, and the Chinese invention application with an application number of 202411131560.0 filed on Aug. 16, 2024, by the applicant. The above-mentioned priority patent applications are incorporated by reference in their entirety.

### TECHNICAL FIELD

The present application relates to the field of display technology, and particularly to a quantum dot material, a method for preparing the same, and a quantum dot film and a backlight module using the same.

### BACKGROUND

The application of quantum dot films in displays is very extensive. By utilizing their characteristics in backlight modules, the brightness, color saturation, and contrast of the display can be improved. The quantum dot materials that constitute quantum dot films are nanocrystalline materials. Due to their size characteristics, the electron-hole pairs present in quantum dot materials will cause energy level quantization of electrons within the quantum dots because the size of the quantum dots is close to the wavelength of the material's matter wave, resulting in an energy gap. Therefore, by changing the size of the quantum dots, the energy gap of the material can be altered, thereby creating optical properties such as adjustable wavelength of light emission.

Among existing quantum dot materials, metal halide perovskite materials have become an important research direction in related fields due to their excellent optoelectronic properties. Metal halide perovskite materials have various crystal structures, such as ABX₃, (AA′)BX₄, A₂BX₄ and other perovskite structures. Due to the quantum confinement effect and changes in halogen sites, perovskite quantum dots can emit light of different wavelengths and possess advantages such as a narrow full width at half maximum of emission spectrum and high photoluminescence quantum yield (PLQY).

However, quantum dot materials have a relatively large surface area, resulting in high surface activity and the tendency to form dangling bonds or defects, leading to the formation of trap states. This causes a decrease in PLQY and poor environmental stability, making the materials prone to degradation or failure due to environmental factors such as water, oxygen, or light and heat, which trigger high surface reactivity.

More specifically, traditional perovskite synthesis methods mainly use oleic acid (OA) and oleylamine (OLA) as ligands for capping quantum dots. However, perovskite quantum dot materials prepared by traditional synthesis methods usually have a high dynamic binding on their surface (generally composed of anionic OA− and cationic OLA+ and oppositely charged crystal surface ions). Due to the mutual balance between ligands, the protective ligand layer on the surface of perovskite quantum dots tends to decompose rapidly during purification, leading to a rapid decline in stability and luminescence efficiency, ultimately forming agglomerated products. Therefore, relying solely on these two ligands for capping will cause ligand detachment due to the dynamic balance between the ligands and the quantum dot surface, leading to quantum dot agglomeration or degradation. Additionally, ligands can lose their coordination ability due to electron or proton exchange between them, resulting in ligand detachment and surface instability of the quantum dot materials, making them difficult to be practically applied and commercialized.

In addition, among the existing preparation methods for metal halide perovskite materials (especially FAPbBr₃), the more common ones are the ligand-assisted reprecipitation method (LARP) and the hot injection method (HI) for synthesis. However, these two preparation methods not only have high costs but also make it difficult to control the quality of the final product, leading to challenges in mass production.

For the LARP synthesis method, it requires the use of costly formamidinium bromide (FABr) and lead bromide (PbBr₂) as precursors, making it difficult to reduce production costs. Additionally, since polar solvents such as dimethylformamide (DMF) or dimethyl sulfoxide are needed in the reaction system, these polar solvents interact with the precursors, causing corrosion of the perovskite nanocrystal structure during synthesis, thereby reducing both yield and luminescence efficiency. As for the HI synthesis method, it typically uses formamidinium acetate (FAAc) in combination with PbBr₂ as dual precursors for synthesis. This method requires a high-temperature, anhydrous, and oxygen-free environment, and the reaction must be rapidly quenched in an ice bath after precursor injection. These difficult-to-control environmental conditions and processes result in poor quality control of the final product and hinder large-scale production.

Furthermore, since both preparation methods require the use of PbBr₂ as a precursor, but the ratio of cations and anions used in the synthesis is related to the proportion of the selected inorganic salt, it is difficult to precisely adjust the composition of the final product.

The aforementioned issues make it challenging to mass-produce perovskite quantum dot materials with good and stable quality that meet the luminescence requirements specified by the International Telecommunication Union Radiocommunication Sector (ITU-R) for high-definition imaging (Rec. 2020, BT.2020).

### SUMMARY

An object of the present application is to provide a quantum dot material and a backlight module using the quantum dot material to address the above problems.

An embodiment of the present application proposes a quantum dot material, including a core layer, a ligand layer and a coating layer. The ligand layer is formed to cover at least part of a surface of the core layer, and forms a bond with the core layer. The coating layer is formed to cover at least part of a surface of the ligand layer, and forms a bond with the ligand layer. The ligand layer is formed from at least three ligand compounds, and the at least three ligand compounds comprise a first type of ligand compound and a second type of ligand compound, and; the first type of ligand compound has a first coordinating group for forming a bond with the core layer, and the second type of ligand compound has a second coordinating group for forming a bond with the coating layer.

An embodiment of the present application proposes a quantum dot material, wherein the organic-inorganic perovskite material has a crystal structure of ABX₃, with A sites occupied by formamidinium ions, B sites occupied by lead ions, and X sites occupied by bromide ions, wherein the organic perovskite material, when the wavelength of incident light is 450 nm, has a maximum emission wavelength between 450 nm and 760 nm, preferably between 525 nm and 535 nm, in response to the incident light.

An embodiment of the present application proposes a quantum dot material, wherein the organic-inorganic perovskite material has a crystal structure of ABX₃, with A sites occupied by formamidinium ions, B sites occupied by lead ions, and X sites occupied by bromide ions, wherein the infrared absorption spectrum of the organic-inorganic perovskite material has a relative peak of stretching vibration in the wavenumber range from 750 cm⁻¹ to 1250 cm⁻¹.

In some embodiments of the present application, the maximum emission wavelength is between 528 nm and 532 nm.

In some embodiments of the present application, the full width at half maximum (FWHM) of the organic-inorganic perovskite material is less than 23 nm.

In some embodiments of the present application, the quantum efficiency range of the organic-inorganic perovskite material is greater than 60%.

In some embodiments of the present application, the quantum efficiency range of the organic-inorganic perovskite material is greater than 90%.

In some embodiments of the present application, the average fluorescence lifetime of the organic-inorganic perovskite material is between 18.3 ns and 30.5 ns.

In some embodiments of the present application, the infrared absorption spectrum of the organic-inorganic perovskite material has a relative peak of stretching vibration in the wavenumber range from 750 cm⁻¹ to 1250 cm⁻¹.

In some embodiments of the present application, the organic-inorganic perovskite material is synthesized from at least three precursors.

In some embodiments of the present application, the at least three precursors include a formamidinium ion precursor, a lead ion precursor, and a bromide ion precursor, wherein the formamidinium ion precursor includes salts for generating formamidinium free base, the lead ion precursor includes lead compounds, and the bromide ion precursor includes organic bromides.

In some embodiments of the present application, the salt used to generate formamidine free base includes formamidine acetate, the lead compound includes at least one of lead acetate and lead oxide, and the organic bromide includes benzoyl bromide.

In some embodiments of the present application, the ligands involved in the reaction during the preparation of the organic-inorganic perovskite material include sulfobetaine and oleic acid.

In some embodiments of the present application, the sulfobetaine includes 3-(N,N-Dimethyloctylammonio) propanesulfonate.

In some embodiments of the present application, the temperature during the preparation of the organic-inorganic perovskite material does not exceed 120° C.

In some embodiments of the present application, the chemical formula of the first type of ligand compound is ZRₙ_{₁}, where Z is the first coordinating group; and Rₙ_{₁} is the first alkane, and n₁ is the number of chains of the first alkane, which is greater than 0.

In some embodiments of the present application, the first type of ligand compound further includes first functional groups, so that the chemical formula of the first type of ligand compound is ZRₙ_{₁}Wₘ₁, where Wₘ₁ is the first functional group, m1 is the number of the first functional groups, which is a positive integer.

In some embodiments of the present application, the first functional group is selected from any one of the following: methyl (—CH₃), ethyl (—C₂H₆), propyl (—C₃H₇), butyl (—C₄H₉), pentyl (—C₅H₁₁), hydroxyl (—OH), amino (—NH₃), and pyridyl (—C₅H₅N).

In some embodiments of the present application, the chemical formula of the second type of ligand compound is ZRₙ_{₂}K_{X}, where Rₙ_{₂} is the second alkane, and n₂ is the number of chains of the second alkane, which is greater than or equal to 0; and K_{X} is the second coordinating group.

In some embodiments of the present application, the second coordinating group is selected from any one of the following: siloxane compounds, titanoxane compounds, zirconoxane compounds, alumoxane compounds, zinc oxane compounds, and thioxane compounds.

In some embodiments of the present application, the second type of ligand compound further includes second functional groups, so that the chemical formula of the second type of ligand compound is: ZRₙ_{₂}K_{X}Wₘ₂, where Wₘ₂ is the second functional group, and m2 is the number of the second functional groups, which is a positive integer.

In some embodiments of the present application, the second functional group is selected from any one of the following: methyl (—CH₃), ethyl (—C₂H₆), propyl (—C₃H₇), butyl (—C₄H₉), pentyl (—C₅H₁₁), hydroxyl (—OH), amino (—NH₃), and pyridyl (—C₅H₅N).

In some embodiments of the present application, the infrared absorption spectrum of the quantum dot material has relative peaks of stretching vibrations in the wavenumber ranges of 750 cm⁻¹ to 850 cm⁻¹, 900 cm⁻¹ to 1000 cm⁻¹, 1050 cm⁻¹ to 1150 cm⁻¹, and 3400 cm⁻¹ to 3500 cm⁻¹.

In some embodiments of the present application, the melting point of at least one of the materials of the coating layer is greater than 60° C.

In some embodiments of the present application, the average fluorescence lifetime of the quantum dot material is less than 120 ns.

In some embodiments of the present application, the A sites of the crystal structure of the core layer are occupied by formamidinium ions, the B sites are occupied by lead ions, and the X sites are occupied by one of chloride ions, bromide ions, and iodide ions, wherein the quantum dot material has a maximum emission wavelength between 450 nm and 760 nm in response to incident light when the wavelength of the incident light is 450 nm.

In some embodiments of the present application, the coating layer is formed based on any one of the following materials: silicon oxide, titanium oxide, aluminum oxide, boron oxide, zinc sulfide, and lead sulfide.

In some embodiments of the present application, the coating layer contains at least one of Tetraethoxysilane (TEOS; CAS NO: 78-10-4), Tetramethyl orthosilicate (TMOS; CAS NO: 681-84-5), 3-Methacryloxypropyltrimethoxysilane (CAS NO: 2530-85-0), Sulphur Powder (CAS NO: 7704-34-9), Selenium Powder (CAS NO: 07782-49-2), and Lead (II) oxide (CAS NO: 1317-36-8).

In some embodiments of the present application, the thickness of the coating layer is between 5 nm and 100 μm.

In some embodiments of the present application, the first coordinating group is selected from any one of the following: carboxyl group (—COOH), sulfonic acid group (—SO₃H), sulfinic acid group (—SOOH), thiosulfonic acid group (—COSH), nitrate ester group (—ONO₂), nitrite ester group (—ONO), cyanate ester group (—OCN), isocyanate ester group (—NCO), phosphate ester group (—OPO(OH)₂), phosphite ester group (—PO(OH)₂), thiol group (—SH), primary amine group (—NH₂), secondary amine group (—NH), and tertiary amine group (—NR₂).

In some embodiments of the present application, the first type of ligand compounds includes at least two of the following: Oleic Acid (CAS NO: 112-80-1), Stearic acid (CAS NO: 57-11-4), 4-Dodecylbenzenesulfonic acid (CAS NO: 121-65-3), 1-Octadecanethiol (CAS NO: 2885-00-9), 2,2′-Iminodiethanol (CAS NO: 111-42-2), Methylammonium acetate (CAS NO: 6998-30-7), and 3-(1-Pyridinio)-1-propanesulfonate (CAS NO: 15471-17-7).

In some embodiments of the present application, the second type of ligand compounds includes at least one of the following: (3-Aminopropyl) triethoxysilane (APTES; CAS NO: 919-30-2), (3-Aminopropyl) trimethoxysilane (APTMS; CAS NO: 13822-56-5), (3-Mercaptopropyl) triethoxysilane (MPTES; CAS NO: 14814-09-6), (3-Mercaptopropyl) trimethoxysilane (MPTMS; CAS No. 4420-74-0), Cysteine (CAS No. 52-90-4), 3-Sulfanylpropanoic acid (CAS No. 107-96-0), ethanolate; titanium (4+) (CAS No: 3087-36-3), Titanium isopropoxide (CAS No: 546-68-9), Titanium tetrachloride (CAS No: 7550-45-0), Trimethylalane (CAS No: 75-24-1), and Zirconyl nitrate (CAS No: 13826-66-9).

In some embodiments of the present application, a main chain length of the first-type ligand compound has a carbon number greater than or equal to 10.

An embodiment of the present application proposes a method for preparing quantum dot materials, including the following steps: mixing a formamidinium ion precursor, a lead ion precursor, and a ligand in a solvent to form a mixed solution; drying the mixed solution at a first temperature; cooling the dried mixed solution to a second temperature lower than the first temperature in an inert gas environment; and injecting a bromide ion precursor into the mixed solution at the second temperature to generate a solution containing the organic-inorganic perovskite material, wherein the generated quantum dot material has a crystal structure of ABX₃, with the A sites occupied by formamidinium ions, the B sites occupied by lead ions, and the X sites occupied by bromide ions.

An embodiment of the present application proposes a method for preparing quantum dot material, including the following steps: providing at least three compounds as precursors for FA ions, Pb ions, and Br ions, respectively; and processing the at least three compounds in an environment not exceeding 120° C. to generate the quantum dot material.

An embodiment of the present application proposes a method for preparing quantum dot material, including the following steps: providing multiple compounds as precursors for FA ions, Pb ions, and Br ions; and providing oleic acid and 3-(N,N-Dimethyloctylammonio)-propanesulfonate
as ligands to react with the precursors to generate the quantum dot materials.

In some embodiments of the present application, the formamidinium ion precursor includes formamidinium acetate.

In some embodiments of the present application, the lead ion precursor includes at least one of lead acetate and lead oxide.

In some embodiments of the present application, the bromide ion precursor includes benzoyl bromide.

In some embodiments of the present application, the ligand includes oleic acid and sulfobetaine.

In some embodiments of the present application, the sulfobetaine includes 3-(N,N-Dimethyloctylammonio)propanesulfonate.

In some embodiments of the present application, the first temperature does not exceed 120° C.

In some embodiments of the present application, the first temperature is greater than or equal to 100° C., and the second temperature is between 40° C. and 75° C.

In some embodiments of the present application, the inert gas is nitrogen.

In some embodiments of the present application, the method for preparing quantum dot materials further includes the following steps: performing a first centrifugation process on a solution containing the organic-inorganic perovskite material to obtain a precipitate; adding an organic solvent to the precipitate and performing a second centrifugation process; and filtering the quantum dot material based on a supernatant after the second centrifugation process.

An embodiment of the present application proposes a quantum dot film applicable for a backlight module, including the quantum dot material as described in any of the previous claims. The quantum dot material is, for example, an organic-inorganic perovskite material, and the organic-inorganic perovskite material includes FAPbBr₃.

An embodiment of the present application proposes a backlight module, including a quantum dot film prepared based on the quantum dot material as described in any of the previous claims.

With the technical solution described in the present application, the quantum dot material proposed in the embodiments of the present application exhibits excellent and stable material properties, particularly in terms of thermal stability, and can produce green light that meets the requirements of the Rec. 2020 standard. Additionally, the quantum dot material proposed in the embodiments of the present application can have a shorter average fluorescence lifetime, reducing fluorescence defects in quantum dots, increasing the proportion of rapid electron-hole recombination, and improving luminous efficiency. The method for preparing a quantum dot material proposed in the embodiments of the present application can synthesize high-performance and high-quality organic perovskite materials using cost-effective tri-precursors in a low-temperature environment, offering higher reproducibility compared to existing methods and being applicable for mass production.

### BRIEF DESCRIPTION OF DRAWINGS

FIG. 1 is a schematic diagram of a display device according to some embodiments of the present application;

FIG. 2 is a schematic diagram of a backlight module according to some embodiments of the present application;

FIGS. 3A to 3C are schematic diagrams of the structure of a quantum dot material according to some embodiments of the present application;

FIGS. 4A and 4B are schematic diagrams of the analysis of a quantum dot material using transmission electron microscopy according to some embodiments of the present application;

FIGS. 5A to 5G are schematic diagrams of the absorption and emission spectra of quantum dot materials in some experimental examples and Comparative Example of the present application;

FIGS. 6A and 6B are time-resolved fluorescence spectra of quantum dot materials in some experimental examples and Comparative Example of the present application;

FIGS. 7A and 7B are fluorescence spectra of quantum dot materials in Comparative Example and Experimental Example 5 of the present application at different temperatures;

FIG. 8 is an analysis spectrum of a quantum dot material using an X-ray diffractometer according to some embodiments of the present application;

FIGS. 9A and 9B are infrared absorption spectra of a quantum dot material according to some embodiments of the present application; and

FIG. 10 is a flowchart of the steps in the manufacturing method of a quantum dot material according to some embodiments of the present application.

### DESCRIPTION OF EMBODIMENTS

To make the objectives, features, and advantages of the technical solution more apparent and easier to understand, the specific embodiments of the proposed technical solution are described in detail below with reference to the accompanying drawings. The descriptions of the various embodiments of the technical solution of this invention are provided for illustrative purposes only and do not represent all embodiments of the invention or limit the invention to specific embodiments. Based on the embodiments in the present application, all other embodiments obtained by those of ordinary skill in the art without creative effort shall fall within the scope of protection of this disclosure.

It should be noted that when an element is referred to as being “mounted on” another element, it can be directly on the other element or there may be an intervening element. When an element is considered to be “connected” to another element, it can be directly connected to the other element or there may be an intervening element. The terms “vertical,” “horizontal,” “left,” “right,” “up,” “down,” and similar expressions used in this document are only intended to indicate relative positional relationships based on the schematic and are not intended to limit the elements described by these terms to be implemented only in the manner indicated. When the absolute position of the described object changes, the description of the relative position may also change accordingly.

In all descriptions related to specific numerical values in the present application, even if not directly stated, they all include the meaning of “approximately” or “substantially,” meaning that these specific numerical values will cover possible ranges of numerical errors, thereby acknowledging possible unexpected impacts and deviations in the process or material selection. The range of numerical errors can include variations that do not significantly alter the structure, properties, or effects of the material, such as a range of 0% to 10% deviation, which is clear to those skilled in the art.

Unless otherwise defined, all technical and scientific terms used in this document have the same meanings as commonly understood by those skilled in the technical field of the present application. The terms used in the description of the present application are for the purpose of describing specific embodiments and are not intended to limit the application. The term “and/or” used in this document includes any and all combinations of one or more related listed items.

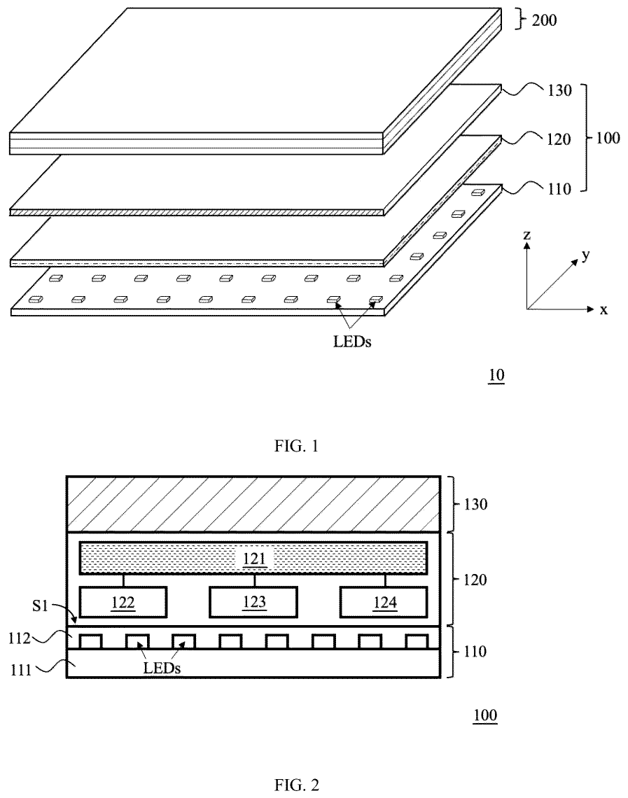

FIG. 1 is a schematic diagram of a display device according to some embodiments of the present application. Referring to FIG. 1, the display device 10 includes a backlight module 100 and a display panel 200, where the backlight module 100 and the display panel 200 are disposed on the x-y plane, and the display panel 200 is disposed on the backlight module 100 along the z axis. The backlight module 100 is used to provide sufficient brightness and uniformly distributed light to the display panel 200. The display panel 200 is used to control and adjust the passing light to display corresponding images. In this embodiment, the display device 10 can be any electronic device with display functionality, such as a television, screen, laptop, or mobile phone, and the present application is not limited to these.

The backlight module 100 includes a light-emitting layer 110, a quantum dot film 120, and an optical adjustment layer 130 disposed sequentially along the z axis, where the quantum dot film 120 is disposed on the light-emitting layer 110, and the optical adjustment layer 130 is disposed on the quantum dot film 120, meaning the quantum dot film 120 is disposed between the light-emitting layer 110 and the optical adjustment layer 130.

The light-emitting layer 110 includes a plurality of light-emitting elements (LEDs) disposed in an array, which can be used to emit light toward the display panel 200. In some embodiments, the light-emitting elements (LEDs) may be blue light-emitting diodes (or light-emitting diodes with emission wavelengths in the blue light range). In some embodiments, the light-emitting elements (LEDs) may be mini-LEDs or micro-LEDs, though the application is not limited thereto. In other embodiments, the light-emitting elements (LEDs) may also be of other sizes and/or types.

The quantum dot film 120 is disposed on the light transmission path of the light-emitting layer 110 and is used to adjust the wavelength of part of the light emitted by the light-emitting elements (LEDs), while allowing another part of the light emitted by the light-emitting elements (LEDs) to pass through without adjustment. For example, when the light-emitting elements (LEDs) emit light in the blue wavelength range (e.g., 400 nm-520 nm), the quantum dot film 120 can adjust the wavelength of the first part of the received light to the red wavelength range (e.g., 610 nm-720 nm), adjust the wavelength of the second part of the received light to the green wavelength range (e.g., 520 nm-610 nm), and maintain the third part of the received light in the blue wavelength range and directly output the third part of the received light without adjustment. Thus, the first to third parts of the light emitted by the light-emitting layer 110 can be mixed to form white light after passing through the quantum dot film 120.

The optical adjustment layer 130 is also located on the light transmission path of the light-emitting layer 110 and is used to adjust the direction of the received light to make the transmitted light more uniform. In some embodiments, the optical adjustment layer 130 includes a plurality of optical microstructures (not shown) and/or optical films (not shown) for adjusting the direction of light, though the application is not limited thereto.

The display panel 200, for example, includes a pixel array substrate, a counter substrate, and a non-self-luminous display medium, where the pixel array substrate and the counter substrate are disposed opposite to each other, and the non-self-luminous display medium is disposed between the pixel array substrate and the counter substrate. In some embodiments, the non-self-luminous display medium may be, for example, liquid crystal, though the application is not limited thereto.

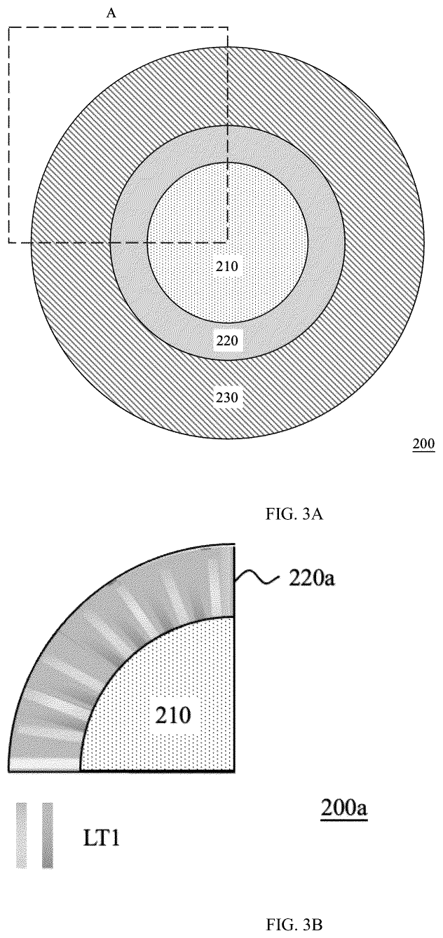

More specifically, the configuration of the backlight module 100 of the embodiment of the application can be as shown in FIG. 2, where FIG. 2 is a schematic diagram of a backlight module according to an embodiment of the application. Referring to FIG. 2, in this embodiment, the light-emitting layer 110 includes light-emitting elements (LEDs), a substrate 111, and a protective layer 112. The light-emitting elements (LEDs) are disposed on the substrate 111 and emit light toward the quantum dot film 120. The protective layer 112 covers the light-emitting elements (LEDs).

The quantum dot film 120 includes an active layer 121, a support layer 122, a bonding layer 123, and a waterproof layer 124. The active layer 121 may include a substrate (not shown) and quantum dot materials (not shown) doped in the substrate, wherein the substrate may be, for example, a light-transmissible macromolecular polymer material (such as resin material), and the quantum dot material may be, for example, semiconductor quantum dots synthesized from nanocrystalline semiconductor materials (such as II-VI semiconductor materials, III-V semiconductor materials, or other composite materials), though the application is not limited thereto. When the quantum dot material is irradiated with light, it emits colored light with a wavelength different from that of the incident light. For example, the quantum dots can emit green light and red light when irradiated with blue light.

The support layer 122 is disposed on a light-emitting surface Si of the light-emitting layer 110 and is used to carry/fix the active layer 121, so that the material of the active layer 121 can be attached/coated on the support layer 122. The support layer 122 may be formed, for example, from organic polymers and/or inorganic materials with light transmittance and certain support properties. The organic polymer may be, for example, Polyvinylidene Chloride (PVdC), Cyclic Olefin Copolymer (COC), High Density Polyethylene (HDPE), Polyethylene terephthalate (PET), Polyimide (PI), Polyethersulfone (PES), Polyethylene Naphthalate (PEN), Polycarbonate (PC), or a combination of the aforementioned materials. The inorganic material may be, for example, metal oxides (such as SiOₓ, SiₓN_{y}, etc.).

In some embodiments, the support layer 122 may be a polymer barrier film formed using PVdC and COC materials, which can provide a certain degree of water and oxygen barrier properties.

The bonding layer 123 is used to provide a bonding force so that the active layer 121 and the support layer 122 can be effectively and reliably adhered/fixed, wherein the bonding layer 123 may be formed, for example, from an Optical Clear Adhesive (OCA) or a surface treatment agent (Primer).

The waterproof layer 124 is directly or indirectly covering at least part of the surface of the active layer 121, thereby preventing the active layer 121 from being affected by moisture and ensuring its normal operation, thus extending the working life of the active layer 121. Specifically, the waterproof layer 124 can be implemented using a protective macromolecular polymer film. For example, the waterproof layer 124 can be made of poly-para-xylylene (Parylene). The poly-para-xylylene has properties such as resistance to high and low temperatures, corrosion resistance, acid and alkali resistance, water and moisture resistance, transparency, and high insulation strength. Therefore, when used as the waterproof layer 124 to cover the active layer 121, it can effectively isolate the impact of moisture on the active layer 121.

In the embodiments of the present application, the quantum dots in the active layer 121 can be implemented using various quantum dot materials with novel structures (e.g., organic-inorganic perovskite materials). In some embodiments, the quantum dot material can be used to emit light that meets the specifications for green light defined by the International Telecommunication Union Radiocommunication Sector (ITU-R) for high-definition imaging (Rec. 2020, BT.2020), i.e., light with CIE-1931 color space coordinates of (0.170, 0.797) and a wavelength between 530 nm and 535 nm. By using the quantum dot material as the main material in the quantum dot film 120/active layer 121, a good green light emission effect can be achieved, and the problems mentioned in the background technology can be resolved.

In addition, the quantum dot material proposed in the embodiments of the present application can also be applied as a substrate for most light-emitting components in the optoelectronic field. For example, the organic-inorganic perovskite material can also be applied in the design of lasers, solar cells, and photodetectors, though the present application is not limited thereto.

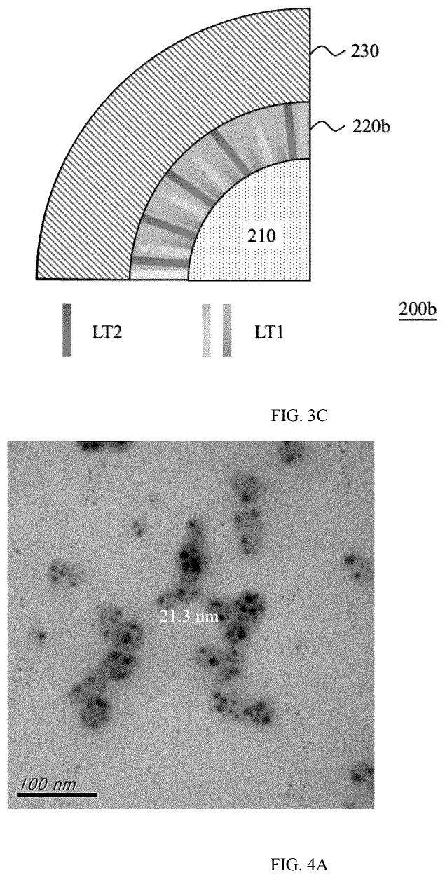

FIGS. 3A to 3C are schematic diagrams of the structure of the quantum dot material in some embodiments of the present application, where FIG. 3A is a cross-sectional schematic diagram of the quantum dot material in some embodiments of the present application, and FIGS. 3B and 3C are enlarged schematic diagrams of local areas of FIG. 3A in different embodiments.

Please refer to FIG. 3A first. The quantum dot material 200 in this embodiment includes a core layer 210 and a ligand layer 220. The ligand layer 220 is formed to cover at least part of the surface of the core layer 210, and forms a bond with the core layer 210. In some embodiments, the quantum dot material 200 may further include a coating layer 230, which can be formed to cover at least part of the surface of the ligand layer 220, and forms a bond with the ligand layer 220.

Specifically, in this embodiment, the core layer 210 can be composed of any nanomaterial with a size smaller than 100 nm. In some embodiments, the material constituting the core layer 210 can be an organic-inorganic perovskite material, which has a crystal structure of ABX₃, where the A sites can be cations such as Cs⁺, FA⁺ (Formamidinium), MA⁺ (methylammonium), . . . etc., the B sites can be divalent metal ions such as Pb²⁺, Sn⁻, and the X sites can be halogens, though the application is not limited thereto. In other embodiments, the material of the core layer 210 can also be formed from nanomaterials with structures such as sphalerite structure and/or wurtzite structure.

In some embodiments, the material of the core layer 210 can be FAPbBr₃, meaning that in the crystal structure of the core layer 210, the A sites are occupied by formamidinium ions, the B sites are occupied by lead ions, and the X sites are occupied by bromide ions. In this embodiment, the quantum dot material 200 can be used to emit light that meets the green light definition in the specifications (Rec. 2020, BT.2020) established by the International Telecommunication Union Radiocommunication Sector (ITU-R) for high-definition images, i.e., light with CIE-1931 color space coordinates of (0.170, 0.797) and a wavelength between 525 nm and 535 nm (when the incident light wavelength is 450 nm). By utilizing the quantum dot material as the main material in the quantum dot film 120/active layer 121, a good green light emission effect can be achieved. In some embodiments of the present application, when the wavelength of the incident light is 450 nm, the quantum dot material 200 has a maximum emission wavelength between 450 nm and 760 nm in response to the incident light, i.e., between the wavelengths of blue light and red light, but the present application is not limited thereto.

The ligand layer 220 can be formed, for example, from various ligand compounds, whose main role is to enable the quantum dots to disperse well in various non-polar organic solvents and improve the surface properties of the overall quantum dot material, such as temperature resistance and compatibility of quantum dots with other materials, further enhancing the optical performance of the quantum dot material.

More specifically, FIG. 3B illustrates a partial cross-sectional structural embodiment of a quantum dot material 200a. The quantum dot material 200a of this embodiment includes a core layer 210 and a ligand layer 220a, wherein the ligand layer 220a may contain a variety of first-type ligand compounds LT1. The chemical formula of the first-type ligand compound LT1 can be, for example, ZRₙ_{₁}Wₘ₁, where Z is the first coordinating group; Rₙ_{₁} is the first alkane, and n1 is the number of chains of the first alkane, which is greater than 0; and Wₘ₁ is the first functional group, m1 is the number of the first functional groups, which is a positive integer or zero.

In some embodiments, the first coordinating group Z in the first-type ligand compound LT1 can be, for example, an organic functional group that can coordinate with the material of the core layer 210. In some embodiments, the first coordinating group Z can be selected from any of the following functional groups: carboxyl group (—COOH), sulfonic acid group (—SO₃H), sulfinic acid group (—SOOH), thiosulfonic acid group (—COSH), nitrate ester group (—ONO₂), nitrite ester group (—ONO), cyanate ester group (—OCN), isocyanate ester group (—NCO), phosphate ester group (—OPO(OH)₂), phosphite ester group (—PO(OH)₂), thiol group (—SH), primary amine group (—NH₂), secondary amine group (—NH), and tertiary amine group (—NR₂), though the application is not limited thereto.

In some embodiments, a main chain length (the one with the largest carbon number among all chains) of the first-type ligand compound LT1 has a carbon number greater than or equal to 10, and the number of π bonds and σ bonds in its molecular structure can be any number and exist in any possible position.

In some embodiments, the first functional group Wₘ₁ is an optional structure in the first-type ligand compound LT1, where m1 is the number of functional groups, which can be a positive integer or zero. In other words, in some embodiments, the chemical formula of the first-type ligand compound LT1 can also be expressed as: ZRₙ_{₁}. The main functions of the first functional group Wₘ₁ are (1) modifying surface defects, (2) blocking water and oxygen, (3) reducing reflection and increasing refractive index, (4) adjusting surface polarity, and/or (5) enhancing conductivity or insulation.

In some embodiments, the first functional group Wₘ₁ may be selected from any of the following functional groups: methyl (—CH₃), ethyl (—C₂H₆), propyl (—C₃H₇), butyl (—C₄H₉), pentyl (—C₅H₁₁), hydroxyl (—OH), amino (—NH₃), and pyridyl (—C₅H₅N), though the application is not limited thereto.

In some embodiments, the first ligand compound LT1 conforming to the above chemical formula may be, for example, Oleic acid (CAS NO: 112-80-1), Stearic acid (CAS NO: 57-11-4), 4-Dodecylbenzenesulfonic acid (CAS NO: 121-65-3), 1-Octadecanethiol (CAS NO: 2885-00-9), 2,2′-Iminodiethanol (CAS NO: 111-42-2), Methylammonium acetate (CAS NO: 6998-30-7), 3-(1-Pyridinio)-1-propanesulfonate (CAS NO: 15471-17-7), and sulfobetaine, either alone or in combination.

In some embodiments, the sulfobetaine may include, for example, 3-(N,N-Dimethyloctylammonio)-propanesulfonate (SBE-18) or other compounds with similar properties, though the application is not limited thereto.

FIG. 3C illustrates another embodiment of a partial cross-sectional structure of a quantum dot material 200b. The quantum dot material 200b of this embodiment includes a core layer 210, a ligand layer 220b, and a coating layer 230, wherein the ligand layer 220b may be formed by at least three or more ligand compounds (referred to as “hybrid treatment”), and the three ligand compounds at least include a first ligand compound LT1 and a second ligand compound LT2. The ligand layer 220b is bonded to the core layer 210 through the first coordinating group in the first ligand compound LT1 and is bonded to the coating layer 230 through the second coordinating group in the second ligand compound LT2.

Specifically, the basis for forming the ligand layer 220b through hybrid treatment lies in adding N types (N≥3) or more of ligand compounds during the synthesis of the quantum dot material 200. In some embodiments, the N types of ligand compounds will include at least two first ligand compounds LT1 and one second ligand compound LT2. Through ligand hybridization, products that meet the desired conditions can be prepared, achieving optimal performance in various aspects. For a description of the first ligand compound LT1, refer to the above embodiments, which will not be repeated here. The characteristics of the second ligand compound LT2 are further explained below.

The general chemical formula of the second type of ligand compound LT2 is: ZRₙ_{₂}K_{X}Wₘ₂, where Z is the first coordinating group; Rₙ_{₂} is the second alkane, and n2 is the number of chains of the second alkane, which is greater than or equal to 0; K_{X} is the second coordinating group; and Wₘ₂ is the second functional group, m2 is the number of the second functional group, which is a positive integer or zero.

Specifically, the second type of ligand compound LT2 can be a coupling agent that conforms to the broad definition in chemical systems. At least one end of its molecule is a compound that can undergo a coordination reaction and stack with the coating layer 230, and the other end is an organic functional group that can undergo a coordination reaction with the core layer 210, serving as a bonding layer connecting organic and inorganic materials.

The first coordinating group Z in the second type of ligand compound LT2 is the same as mentioned above, being an organic functional group that can coordinate with the material of the core layer 210. Similar parts will not be repeated here.

The number of chains of the second alkane Rₙ_{₂} is greater than or equal to 0, and the number of π and σ bonds in its molecular structure can be any number and exist in any possible position.

The second coordinating group K_{X} can be any group that is grafted through chemical and physical bonds. The second coordinating group K_{X} is located at the end that does not coordinate with the core layer 210 and contains at least X groups, where X is a positive integer. In some embodiments, the second coordinating group K_{X} can be selected from any of the following compounds for implementation: siloxane compounds, titanoxane compounds, zirconoxane compounds, aluminoxane compounds, zinc oxane compounds, and thioxane compounds, though the present application is not limited thereto.

The second functional group Wₘ₂ is an optional structure in the second type of coordination compound LT2, where m2 is the number of functional groups, which can be a positive integer or zero. In other words, in some embodiments, the general chemical formula of the second type of coordination compound LT2 can also be expressed as: ZRₙ_{₂}K_{X}. The function of the second functional group Wₘ₂ is similar to that of the first functional group Wₘ₁, and its structure and implementation examples can refer to the above embodiments and will not be repeated here.

In some embodiments, the second type of ligand compound LT2 conforming to the above chemical general formula may be, for example, at least one of the following: (3-Aminopropyl) triethoxysilane (APTES; CAS NO: 919-30-2), (3-Aminopropyl) trimethoxysilane (APTMS; CAS NO: 13822-56-5), (3-Mercaptopropyl) triethoxysilane (MPTES; CAS NO: 14814-09-6), (3-Mercaptopropyl) trimethoxysilane (MPTMS; CAS No. 4420-74-0), Cysteine (CAS No. 52-90-4), 3-Sulfanylpropanoic acid (CAS No. 107-96-0), ethanolate; titanium (4+) (CAS No: 3087-36-3), Titanium isopropoxide (CAS No: 546-68-9), Titanium tetrachloride (CAS No: 7550-45-0), Trimethylalane (CAS No: 75-24-1), and Zirconyl nitrate (CAS No: 13826-66-9), though the application is not limited thereto.

The material of the coating layer 230 can be any material that can coordinate with the second type of ligand compound LT2 and can cross-link with homologous substances to stack and thicken the shell structure through covalent bonds, ionic bonds, or metallic bonds. In some embodiments, the material of the coating layer 230 may be, for example, silicon oxide, titanium oxide, aluminum oxide, boron oxide, zinc sulfide, lead sulfide, etc., though the application is not limited thereto.

In some specific embodiments, the coating layer 230 may include at least one of or more of the following: Tetraethoxysilane (TEOS; CAS NO: 78-10-4), Tetramethyl orthosilicate (TMOS; CAS NO: 681-84-5), 3-Methacryloxypropyltrimethoxysilane (CAS NO: 2530-85-0), Sulphur Powder (CAS NO: 7704-34-9), Selenium Powder (CAS NO: 07782-49-2), and Lead(II) oxide (CAS NO: 1317-36-8), though the application is not limited thereto. In addition, in some embodiments, the thickness of the coating layer 230 may be, for example, between 5 nm and 100 μm.

In summary, the quantum dot material 200a in the embodiment of FIG. 3B of the present application is a quantum dot structure synthesized using the first type of ligand compound LT1 and the core layer 210 material. The quantum dot material 200b in the embodiment of FIG. 3C of the present application is hybridized with specific multiple ligands, followed by a coating process, to alter the physical properties of the quantum dot luminescent material in a composite manner. Hybridizing the ligands of the quantum dot material means introducing different composite elements or compounds into the structure, which will change the optical properties, electronic properties, and environmental stability of the quantum dots, including resistance to light, heat, water, oxygen, and other chemical properties.

The type, proportion, and amount of ligands added during the synthesis process can serve as important parameters for adjusting the core layer. Additionally, selecting appropriate ligands can allow for outward stacking, facilitating the grafting of the coating layer and reducing the difficulty of synthesis.

It should be noted here that although the quantum dot material 200 depicted in FIGS. 3A to 3C is composed of a single core layer 210, ligand layer 220, and coating layer 230 disposed in sequence, the present application is not limited thereto. In other embodiments, the quantum dot material 200 may also include multiple core layers 210 and ligand layers 220 disposed in an overlapping manner, with the coating layer 230 encapsulating the multiple core layers 210 and ligand layers 220. The present application is not limited thereto.

In some embodiments, the core layer 210 of the quantum dot material 200a/200b can be synthesized using at least three precursors. The at least three precursors include a formamidinium ion precursor, a lead ion precursor, and a bromide ion precursor, where the formamidinium ion precursor includes salts used to generate formamidine free base, the lead ion precursor includes lead compounds, and the bromide ion precursor includes organic bromides. Furthermore, in some embodiments, the salts used to generate formamidine free base include formamidinium acetate, the lead compounds include at least one of lead acetate and lead oxide, and the organic bromides include benzoyl bromide.

In some embodiments, the compounds used to form the ligand layers 220a/220b of the quantum dot materials 200a/200b may include oleic acid (OA) and sulfobetaine. The sulfobetaine may, for example, be 3-(N,N-Dimethyloctylammonio)-propanesulfonate.

In some embodiments, the quantum dot material 200b can utilize a mixture of oleic acid (OA) and stearic acid (SA) combined with a mixture of oleylamine (OAm) and stearamide (SAm) to form the ligand layer 220b.

In some embodiments, the melting point of at least one of the materials used to form the coating layer 230 is greater than 60° C. Specifically, the various novel quantum dot materials proposed in the embodiments of the present application include (1) a synthesis method/structure using sulfobetaine as a ligand to replace the traditional OLA as a ligand (as shown in FIG. 3B or FIG. 3C); and (2) using a hybrid synthesis method that includes at least two first-type ligand compounds LT1 and one second-type ligand compound LT2 as ligands to form the quantum dot material 200b structure as shown in FIG. 3C. In the above-mentioned type (1) embodiment, sulfobetaine is used as a ligand to replace the traditional synthesis method using OLA as a ligand, where replacing OLA with sulfobetaine allows the preparation process to be maintained below 120° C., thus making the overall synthesis reaction less intense, and enabling more precise control of the material particle size during the preparation process, which is applicable for large-scale production.

In the above-mentioned type (2) embodiment, specific different types of ligand compounds LT1 and LT2 are used for the preparation of quantum dot materials, which can give the quantum dot material 200b a ligand layer 220b structure that can be grafted with the coating layer 230, thereby making the physical and chemical properties of the quantum dot material 200b more stable.

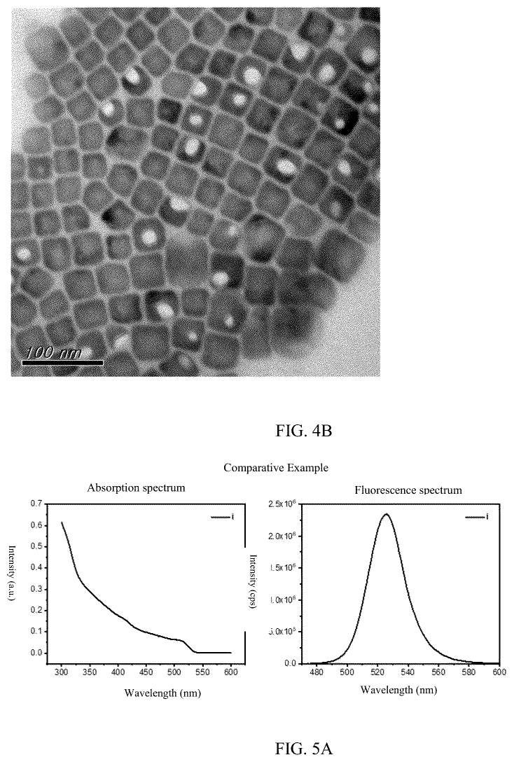

FIGS. 4A and 4B are schematic diagrams of transmission electron microscopy analysis of quantum dot materials in different embodiments of the present application. Please refer to FIG. 4A first, where dark nanocrystals can be seen, which are the core layer 210 of the quantum dot material 200 in the embodiment of the present application, and the lighter-colored outer part is the coating layer 230. According to FIG. 4A, the shape of the quantum dot material 200 can be any form, and it is not limited to whether the core layer 210 shares the coating layer 230.

Please refer to FIG. 4B, which is an experimental example of quantum dot material composed of FAPbBr₃. In FIG. 4B, it can be observed that the quantum dot material in the embodiment of the present application exhibits a well and uniformly distributed cubic structure, where the particle size of FAPbBr₃ is about 30 nm. In some embodiments, the particle size of the cubic crystal structure FAPbBr₃ can range from 10 nm to 35 nm, though the present application is not limited thereto.

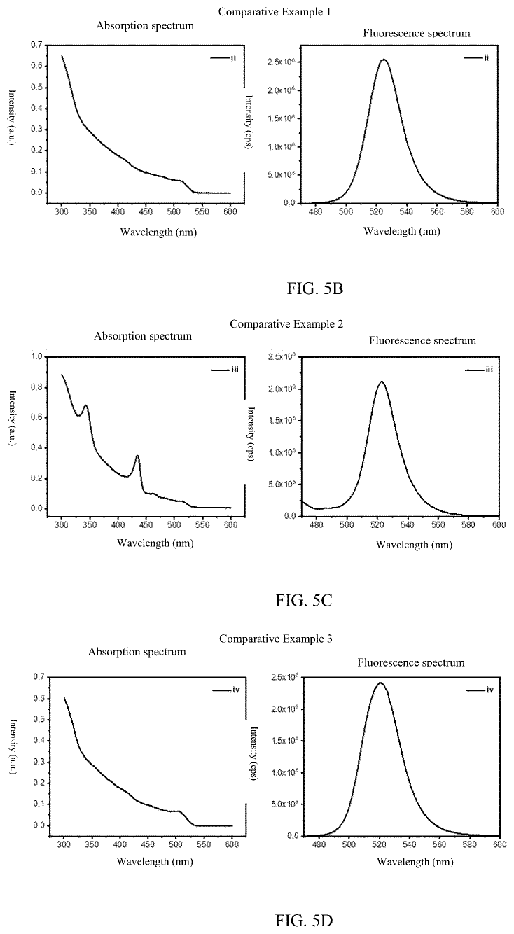

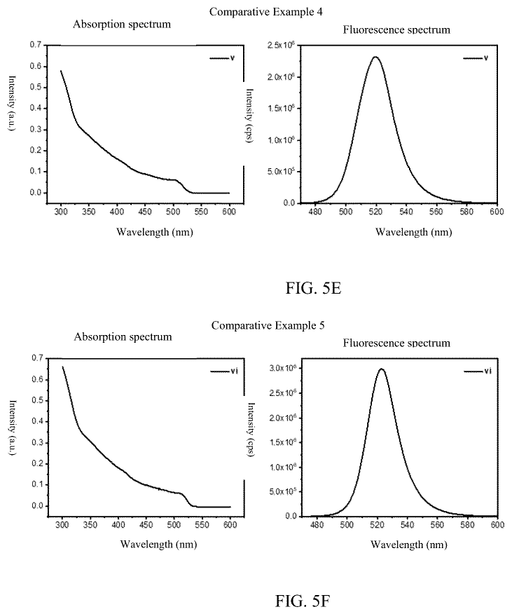

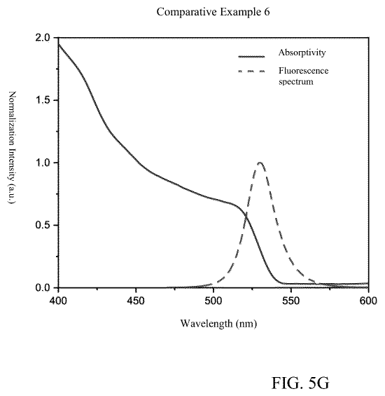

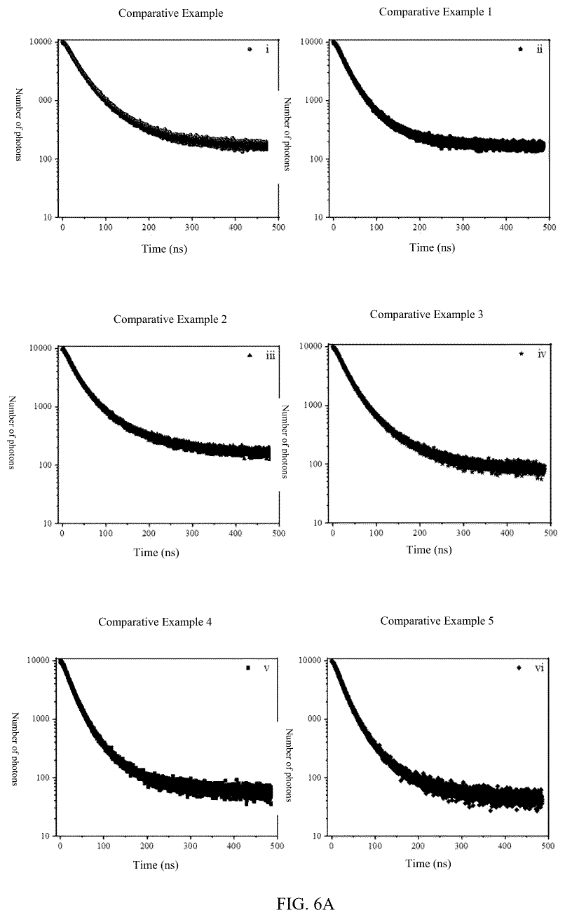

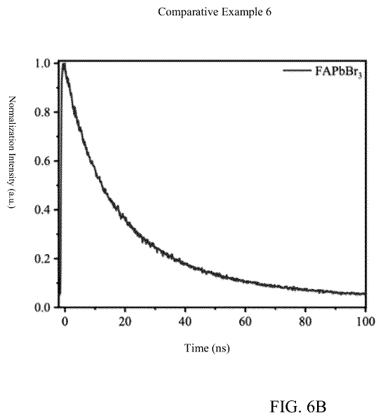

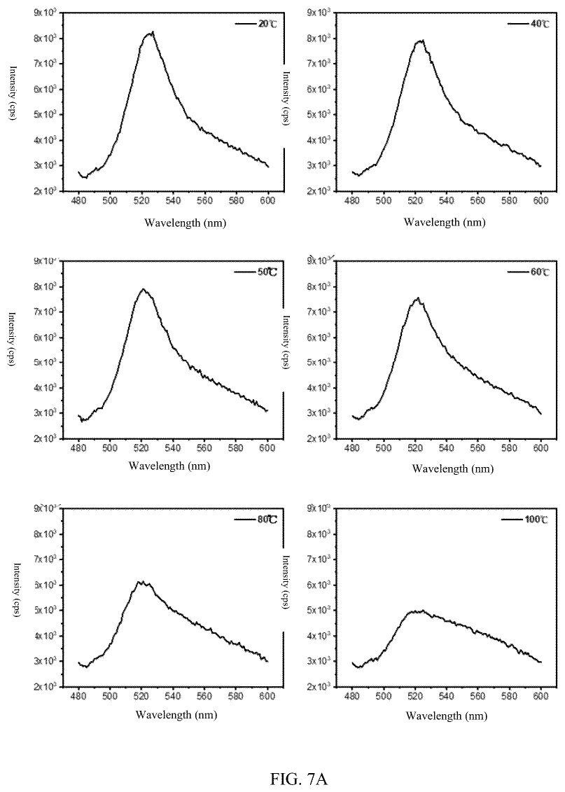

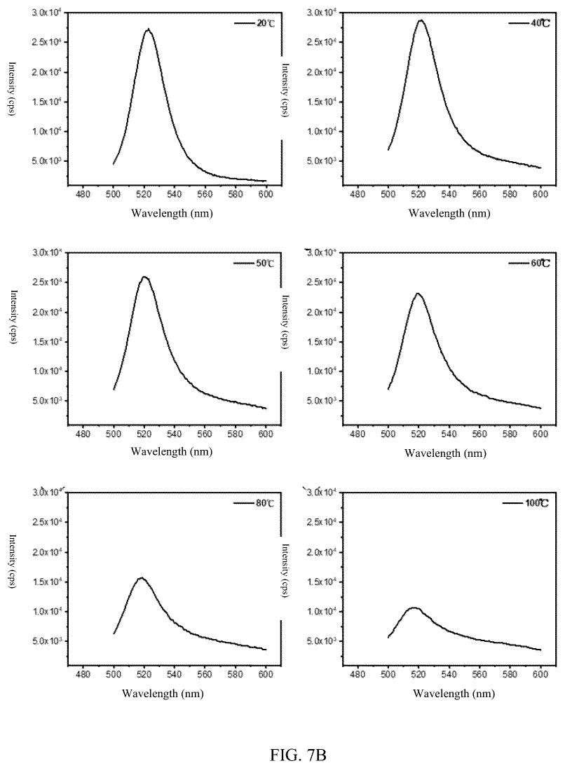

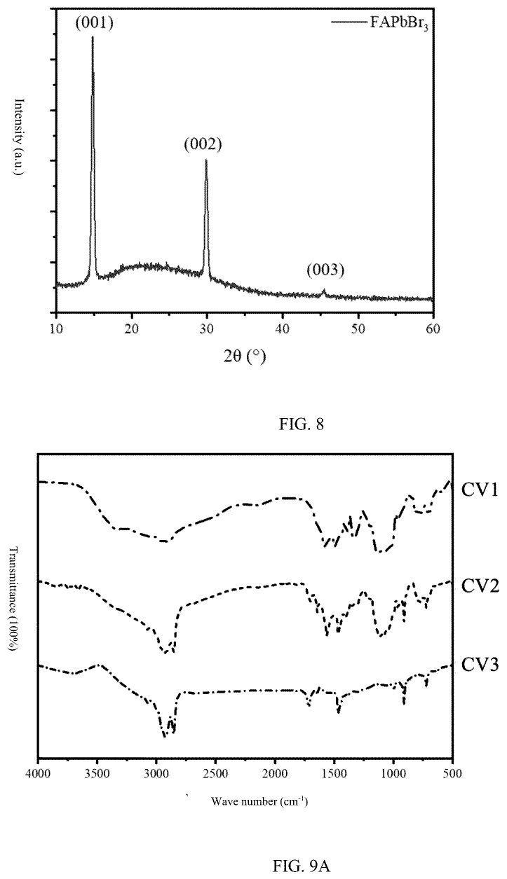

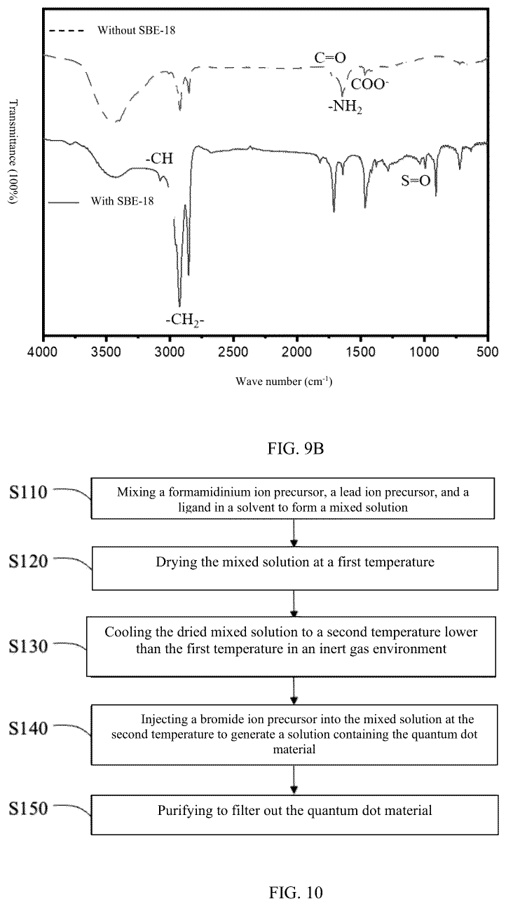

The following figures, from FIG. 5A to FIG. 9B, further illustrate the comparative characteristics of the quantum dot materials in various specific experimental examples of the present application. FIGS. 5A to 5G show the absorption and emission spectra of some experimental examples and Comparative Example of the quantum dot materials of the present application. FIGS. 6A and 6B depict the time-resolved fluorescence spectra of some experimental examples and Comparative Example of the quantum dot materials of the present application. FIGS. 7A and 7B present the fluorescence spectra of the quantum dot materials of the Comparative Example and Experimental Example 5 at different temperatures. FIG. 8 displays the X-ray diffraction analysis patterns of the quantum dot materials in some embodiments of the present application. FIGS. 9A and 9B illustrate the infrared absorption spectra of the quantum dot materials in some embodiments of the present application.

TABLE 1

| | Ligand 1 | Ligand 2 | Ligand 3 | Ligand 4 | Ligand 5 |
|---|---|---|---|---|---|
| | (OA) | (SA) | (OAm) | (SAm) | (SBE-18) |
| Comparative | 0.0025 | 0 | 0.0016 | 0 | 0 |
| Example | | | | | |
| Experimental | 0.00235 | 0.00015 | 0.0016 | 0 | 0 |
| Example 1 | | | | | |
| Experimental | 0.0022 | 0.0003 | 0.0016 | 0 | 0 |
| Example 2 | | | | | |
| Experimental | 0.0025 | 0 | 0.0014 | 0.00015 | 0 |
| Example 3 | | | | | |
| Experimental | 0.0025 | 0 | 0.0012 | 0.0003 | 0 |
| Example 4 | | | | | |
| Experimental | 0.0022 | 0.0003 | 0.0012 | 0.0003 | 0 |
| Example 5 | | | | | |
| Experimental | 0.0025 | 0 | 0 | 0 | 0.084 |
| Example 6 | | | | | |

As shown in Table 1, the Comparative Example is a perovskite quantum dot material formed using only ligand 1 (OA) and ligand 2 (SA). Experimental Examples 1 to 5 correspond to the quantum dot materials of the above-mentioned type (2) embodiment, where Experimental Examples 1 and 2 are perovskite quantum dot materials formed by mixing ligand 1, ligand 2, and ligand 3 (OAm); Experimental Examples 3 and 4 are perovskite quantum dot materials formed by mixing ligand 1, ligand 3, and ligand 4 (SAm); and Experimental Example 5 is the perovskite quantum dot material formed by mixing ligands 1 to 4. Experimental example 6 corresponds to the quantum dot material of the above-mentioned type (1) embodiment, where Experimental Example 6 is the FAPbBr₃ perovskite quantum dot material formed by mixing ligand 1 and ligand 5 (SBE-18) (hereinafter, the quantum dot material of Experimental Example 6 will be referred to as FAPbBr₃).

Please refer to FIGS. 5A to 5F. From the absorption spectra and emission parameters of this embodiment, it can be observed that although the Comparative Example and Experimental Examples 1-5 have different ligand hybridization methods and ratios, the spectral characteristics they exhibit generally align with the target spectral position of the quantum dot materials. In other words, the quantum dot materials formed through ligand hybridization in the embodiments of the present application do not experience unstable optical properties due to changes in the ligand addition ratio.

Please refer to FIG. 5G. In this experimental example, the FAPbBr₃ has a maximum emission wavelength between 525 nm and 535 nm in response to the incident light when the wavelength of the incident light is 450 nm, and the full width at half maximum (FWHM) is less than 23 nm.

In some experimental examples, using hexane as the background solvent for measurement and under the test condition where the absorbance is defined as 0.1, the material FAPbBr₃ of the embodiments of the present application has a maximum emission wavelength of 530±2 nm (i.e., between 528 nm and 532 nm), and the FWHM is 22±1 nm. Additionally, under the aforementioned test conditions, the quantum efficiency range can be calculated to be greater than 90%.

The quantum efficiency range can be measured using a fluorescence spectrometer (e.g., FluoroMax® 4 Fluorometer) in combination with an integrating sphere device (e.g., Quanta-φ). The measurement method can involve placing the sample to be tested and the integrating sphere device in the sample chamber, where the sample is excited by incident excitation light entering the integrating sphere, causing the sample to emit light and generate reflections within the sphere. The quantum efficiency is then calculated by collecting the light exiting the sphere at a specific position. However, the present application is not limited thereto method.

Please refer to FIG. 6A first, which sequentially presents the time-resolved fluorescence spectra of the Comparative Example and Experimental Examples 1 to 5. Based on the quadratic nonlinear fitting parameters calculated from the time-resolved fluorescence spectra in FIG. 6, it can be observed that compared to the Comparative Example using only ligands 1 and 3, Experimental Examples 1 and 2, which include ligand 2 (SA) in ligand 1, show a decreasing trend in average fluorescence lifetime. For example, the average fluorescence lifetime calculated for the Comparative Example is approximately 60.029 ns, while the average fluorescence lifetimes calculated for Experimental Examples 1 and 2 are approximately 49.694 ns and 52.445 ns, respectively.

On the other hand, for Experimental Examples 3 and 4, which mix ligand 4 with ligand 3, as the amount of ligand 4 increases, Experimental Examples 3 and 4 also show a significant decreasing trend compared to the Comparative Example does. For example, the average fluorescence lifetimes calculated for Experimental Examples 3 and 4 are approximately 48.133 ns and 43.881 ns, respectively. For Experimental Example 5, which mixes ligand 2 with ligand 1 and ligand 4 with ligand 3, the average fluorescence lifetime can be reduced to 35.529 ns.

In other words, in some embodiments, the quantum dot material 200b with a ligand layer 220b formed after hybrid treatment can have an average fluorescence lifetime reduced to less than 55 ns. Therefore, FIG. 6A and related calculation results can prove that when appropriate ligands are selected for hybridization to form the ligand layer 220b, the fluorescence defects of the quantum dot material can be reduced, and the proportion of rapid electron-hole pair recombination can be increased, resulting in better light emission efficiency.

Please refer to FIG. 6B. In this embodiment, by performing a quadratic nonlinear fitting operation on the TRPL spectral data, two complex factors can be derived. One of these two complex factors can be defined as related to the trapping rate of photons by defects in the material itself, and the other can be defined as related to the recombination rate constant of photons and the trapping rate constant of photons. Subsequently, the average fluorescence lifetime FAPbBr₃ can be calculated from these two complex factors, ranging between 21.9 ns and 26.6 ns. In some experimental cases, the calculated average fluorescence lifetime is 24.4 ns.

FIG. 7A sequentially presents the fluorescence spectra of the quantum dot material from Comparative Example under 20° C., 40° C., 50° C., 60° C., 80° C., and 100° C. from the top left to the bottom right. The experimental results from FIG. 7A clearly show that if perovskite quantum dots are synthesized using only oleic acid and oleylamine as ligands, their fluorescence intensity begins to decrease with increasing temperature when the temperature rises to 40° C. Additionally, the blue shift in the emission wavelength indicates that the perovskite quantum dots decompose due to high heat.

Similarly, FIG. 7B sequentially presents the fluorescence spectra of the quantum dot material from Experimental Example 5 under 20° C., 40° C., 50° C., 60° C., 80° C., and 100° C. from the top left to the bottom right. The experimental results from FIG. 7B show that the thermal stability of the perovskite quantum dot material synthesized through the hybrid treatment in the embodiment of the present application has significantly improved. As shown in FIG. 7B, the fluorescence intensity of the perovskite quantum dot material from Experimental Example 5 slightly increases at 40° C., and it only decreases and exhibits a blue shift due to high heat after 50° C.

FIG. 8 shows the analysis spectrum of the FAPbBr₃ X light diffractometer in some embodiments of the present application. Referring to FIG. 8, in this embodiment, three main peaks of FAPbBr₃ can be observed, corresponding to the crystal planes of (001), (002), and (003), indicating that FAPbBr₃ has a well-defined Pm3m cubic structure.

FIGS. 9A and 9B show the infrared absorption spectra of quantum dot materials in some embodiments of the present application. In FIG. 9A, the core layer of the quantum dot material is exemplified by perovskite material, and the second type of ligand compound LT2 in the ligand layer is exemplified by siloxane compound, meaning that the ligand layer of the quantum dot material in this embodiment will form a coordination reaction with the coating layer through the siloxane compound, though the present application is not limited thereto. FIG. 9B compares the infrared absorption spectra differences between the FAPbBr₃ of Experimental Example 6 and other common perovskite quantum dots.

Referring to FIG. 9A, characteristic curve CV1 is the transmittance characteristic curve of the siloxane compound used to form the second type of ligand compound LT2, characteristic curve CV2 is the transmittance characteristic curve of the material mixed with the first type of ligand compound LT1 and the second type of ligand compound LT2, and characteristic curve CV3 is the transmittance characteristic curve of the perovskite quantum dot material formed based on the aforementioned first type of ligand compound LT1 and the second type of ligand compound LT2.

In FIG. 9A, it can be observed that after adding the second type of ligand compound LT2, the quantum dot material will have relative peaks of stretching vibration in the corresponding wavenumber range. In this embodiment, whether it is the material mixed with the first type of ligand compound LT1 and the second type of ligand compound LT2 or the quantum dot material formed based on the above ligand compounds, there are relative peaks of stretching vibration in the wavenumber ranges of 3422 cm⁻¹ (representing the characteristic peak of the Si—OH bond), 1094 cm⁻¹ (representing the characteristic peak of the Si—O—Si bond), 957 cm⁻¹ (representing the characteristic peak of the Si—OH bond), and 802 cm⁻¹ (representing the characteristic peak of the Si—O bond).

Therefore, if relative peaks of stretching vibrations are observed in the infrared absorption spectrum of the quantum dot material within the wavenumber ranges of 750 cm⁻¹ to 850 cm⁻¹, 900 cm⁻¹ to 1000 cm⁻¹, 1050 cm⁻¹ to 1150 cm⁻¹, and 3400 cm⁻¹ to 3500 cm⁻¹, it indicates that the quantum dot material has been formed with a ligand layer containing the first type of ligand compound LT1 and the second type of ligand compound LT2 through the hybrid treatment of the embodiments of the present application.

Please refer to FIG. 9B, where it can be observed that the FAPbBr₃ of Experimental Example 6 has a relative peak of stretching vibration within the wavenumber range of 750 cm⁻¹ to 1250 cm⁻¹ compared to other common perovskite quantum dots.

In some experimental examples, FAPbBr₃ has a peak of S═O stretching vibration at a wavenumber of 1035 cm⁻¹, primarily due to the use of sulfobetaine as the ligand during synthesis in the embodiments of the present application (this part will be further described in the subsequent preparation method examples).

Through the above measurement results, it can be found that the FAPbBr₃ of Experimental Example 6 has good and stable material properties and can produce green light that meets the requirements of the Rec. 2020 standard.

The following further illustrates the method for preparing a quantum dot material of the embodiments of the present application with FIG. 10, where FIG. 10 is a flowchart of the steps of the manufacturing method of the quantum dot material in some embodiments of the present application.

In step S110, the formamidinium ion precursor may include, for example, formamidinium acetate (FAAc), and the lead ion precursor may include, for example, at least one of lead acetate (PbAc) and lead oxide (PbO). The ligand may include, for example, oleic acid (OA) and sulfobetaine, where the sulfobetaine may include, for example, 3-(N,N-Dimethyloctylammonio)-propanesulfonate (SBE-18).

In some experimental examples, in step S110, FAAc, PbO, SBE-18, and OA are mixed in a certain proportion using 1-Octadecene (ODE) as the solvent to form a mixed solution. The proportion can be, for example, 105:66:42:5:1.25 (FAAc:PbO:SBE-18:ODE:OA), though the present application is not limited thereto.

Next, the mixed solution formed in step S110 is dried at a first temperature (step S120).

In step S120, the first temperature is, for example, a temperature not exceeding 120° C., e.g., 100° C.

In some experimental examples, step S120 involves heating the mixed solution at 100° C. under vacuum for 30 minutes, though the present application is not limited thereto.

Next, the dried mixed solution is cooled to a second temperature lower than the first temperature in an inert gas environment (step S130), and at the second temperature, a bromide ion precursor is injected into the mixed solution to generate a solution containing the organic-inorganic perovskite material (step S140).

In step S130, the inert gas can be, for example, nitrogen, and the second temperature can be, for example, between 40° C. and 75° C.

In some experimental examples, step S130 involves cooling the mixed solution to 60° C. in a nitrogen environment before proceeding to step S140.

In step S140, the bromide ion precursor includes, for example, benzoyl bromide.

In some experimental examples, when benzoyl bromide is injected into the mixed solution in step S140, benzoyl bromide reacts with OA to release hydrobromic acid (HBr), where HBr is used to synthesize the final FAPbBr₃.

Through the above steps S110-S140, FAPbBr₃ with a ABX₃ crystal structure and material properties as described in Experimental Example 6 can be generated. The FAPbBr₃ synthesized through the above experimental examples has an emission wavelength of approximately 530 nm, FWHM of approximately 21.6 nm and a calculated quantum efficiency of approximately 95.7% under test conditions with an excitation wavelength of 450 nm and an absorbance defined as 0.1.

After step S140, the generated FAPbBr₃ can be further purified (step S150) to utilize the processed FAPbBr₃ material for making quantum dot films. In some embodiments, the purification process may include, for example, the following steps: performing a first centrifugation on a solution containing FAPbBr₃ to obtain a precipitate; adding an organic solvent to the precipitate and performing a second centrifugation; and filtering out the FAPbBr₃ material based on the supernatant after the second centrifugation.

In the experimental procedure of the aforementioned purification process, the first centrifugation may be performed at 15000 rpm for 5 minutes after adding toluene to the solution containing FAPbBr₃; then, the precipitate is mixed with hexane and centrifuged again at 15000 rpm for 5 minutes, and the resulting supernatant is the final product.

Compared to existing methods of preparing FAPbBr₃, the preparation method in the embodiments of the present application synthesizes FAPbBr₃ using at least three precursors. Since it does not require the use of costly FABr and PbBr₂, it can effectively reduce production costs. Additionally, since the preparation method in the embodiments of the present application does not require the use of DMF or DMSO as polar solvents, there is no issue of crystal structure corrosion during synthesis, which could lead to reduced yield and luminescence efficiency. The final produced material has also been verified to have a good and complete structure.

Furthermore, since the preparation method in the embodiments of the present application can perform bromine precursor injection at low temperatures (approximately 40° C.-75° C.), it is less likely to be affected by temperature factors, which could cause FAPbBr₃ to deteriorate and decompose.

In summary, the method for preparing a quantum dot material described in the embodiment of FIG. 10 has higher reproducibility, lower cost, and can be performed at low temperatures compared to existing methods. The produced quantum dot material also has good material properties and can emit highly saturated green light.

It is worth mentioning that the quantum dot material proposed in the embodiments of the present application can also be applied as a substrate for most light-emitting components in the optoelectronic field. For example, the quantum dot material can also be used in the design of lasers, solar cells, and photodetectors, though the present application is not limited thereto

Additionally, it should be noted that in order to clearly illustrate the various inventive features of the present application, the description is divided into multiple embodiments as described above. However, this does not mean that each embodiment can only be implemented individually. Those skilled in the art can, based on their needs, combine feasible implementation examples or replace/combine parts from different embodiments according to the preparation process. In other words, the implementation methods taught in the present application are not limited to the aspects described in the following embodiments, but also include the replacement, combination, and permutation of various embodiments/structures/processes where feasible, as stated here. For example, although Experimental Example 6 is a quantum dot material generated without hybrid treatment, in some embodiments, it can further undergo the hybrid treatment of Experimental Examples 1-5 to form the structure of the ligand layer 220b as shown in FIG. 3C, thereby further enhancing the overall material properties. The present application does not limit individual embodiments/experimental examples to being implemented separately.

Although the present application has been disclosed using the above embodiments, it is not intended to limit the application. Any person skilled in the art, without departing from the spirit and scope of the present application, can make various changes and modifications to the above embodiments, which still fall within the technical scope protected by the present application. Therefore, the protection scope of the present application shall be determined by the claims.

What is claimed is:

1. A quantum dot material, comprising:
a core layer;
a ligand layer, formed to cover at least part of a surface of the core layer, and forming a bond with the core layer; and
a coating layer, formed to cover at least part of a surface of the ligand layer, and forming a bond with the ligand layer,
wherein the ligand layer is formed from at least three ligand compounds, and the at least three ligand compounds comprise a first type of ligand compound and a second type of ligand compound,
wherein the first type of ligand compound has a first coordinating group for forming a bond with the core layer, and the second type of ligand compound has a second coordinating group for forming a bond with the coating layer,
wherein the core layer has a crystal structure of ABX₃, with A sites of the crystal structure of the core layer occupied by formamidinium ions, B sites occupied by lead ions, and X sites occupied by one of chloride ions, bromide ions, and iodide ions,
wherein the quantum dot material, when a wavelength of incident light is 450 nm, has a maximum emission wavelength ranging from 450 nm to 760 nm in response to the incident light.

2. The quantum dot material according to claim 1, wherein the first type of ligand compound has a chemical formula of ZRₙ_{₁}, where Z is the first coordinating group; and Rₙ_{₁} is a first alkane, and n₁ is a number of chains of the first alkane, which is greater than 0.

3. The quantum dot material according to claim 2, wherein the first type of ligand compound further comprises first functional groups, so that the chemical formula of the first type of ligand compound is: ZRₙ_{₁}, Wₘ₁, where Wₘ₁ is the first functional group, m1 is a number of the first functional groups, which is a positive integer.

4. The quantum dot material according to claim 3, wherein the first functional group is selected from any one of the following: methyl (—CH₃), ethyl (—C₂H₆), propyl (—C₃H₇), butyl (—C₄H₉), pentyl (—C₅H₁₁), hydroxyl (—OH), amino (—NH₃), and pyridyl (—C₅H₅N).

5. The quantum dot material according to claim 2, wherein the second type of ligand compound has a chemical formula of ZRₙ_{₂}K_{X}, where Rₙ_{₂} is a second alkane, and n₂ is a number of chains of the second alkane, which is greater than or equal to 0; and K_{X} is the second coordinating group.

6. The quantum dot material according to claim 5, wherein the second coordinating group is selected from any one of the following: siloxane compound, titanoxane compound, zirconoxane compound, alumoxane compound, zinc oxane compound, and thioxane compound.

7. The quantum dot material according to claim 5, wherein the second type of ligand compound further comprises second functional groups, so that the chemical formula of the second type of ligand compound is: ZRₙ_{₂}K_{X}Wₘ₂, where Wₘ₂ is the second functional group, m2 is a number of the second functional groups, which is a positive integer.

8. The quantum dot material according to claim 7, wherein the second functional group is selected from any one of the following: methyl (—CH₃), ethyl (—C₂H₆), propyl (—C₃H₇), butyl (—C₄H₉), pentyl (—C₅H₁₁), hydroxyl (—OH), amino (—NH₃), and pyridyl (—C₅H₅N).

9. The quantum dot material according to claim 1, wherein the infrared absorption spectrum of the quantum dot material has relative peaks of stretching vibrations in wavenumber ranges of 750 cm⁻¹ to 850 cm⁻¹, 900 cm⁻¹ to 1000 cm⁻¹, 1050 cm⁻¹ to 1150 cm⁻¹, and 3400 cm⁻¹ to 3500 cm⁻¹.

10. The quantum dot material according to claim 1, wherein a melting point of at least one of materials of the coating layer is greater than 60° C.

11. The quantum dot material according to claim 1, wherein an average fluorescence lifetime of the quantum dot material is less than 120 ns.

12. The quantum dot material according to claim 1, wherein the at least three ligand compounds comprise sulfobetaine and oleic acid.

13. The quantum dot material according to claim 12, wherein the sulfobetaine comprise 3-(N,N-Dimethyloctylammonio)-propanesulfonate.

14. The quantum dot material according to claim 1, wherein the coating layer is formed based on any one of the following materials: silicon oxide, titanium oxide, aluminum oxide, boron oxide, zinc sulfide, and lead sulfide.

15. The quantum dot material according to claim 1, wherein the coating layer contains at least one of the following: Tetraethoxysilane (TEOS; CAS NO: 78-10-4), Tetramethyl orthosilicate (TMOS; CAS NO: 681-84-5), 3-Methacryloxypropyltrimethoxysilane (CAS NO: 2530-85-0), Sulphur Powder (CAS NO: 7704-34-9), Selenium Powder (CAS NO: 07782-49-2), and Lead(II) oxide (CAS NO: 1317-36-8).

16. The quantum dot material according to claim 1, wherein the coating layer has a thickness ranging from 5 nm to 100 μm.

17. The quantum dot material according to claim 1, wherein the maximum emission wavelength is between 525 nm and 535 nm, and a full width at half maximum (FWHM) of the quantum dot material is between 15 nm and 30 nm.

18. The quantum dot material according to claim 1, wherein a quantum efficiency range of the quantum dot material is greater than 90%.

19. The quantum dot material according to claim 1, wherein the average fluorescence lifetime of the quantum dot material is between 18.3 ns and 30.5 ns.

20. The quantum dot material according to claim 1, wherein the infrared absorption spectrum of the quantum dot material has a relative peak of stretching vibration in the wavenumber range of 750 cm⁻¹ to 1250 cm⁻¹.

21. The quantum dot material according to claim 1, wherein the first coordinating group is selected from any one of the following: carboxyl group (—COOH), sulfonic acid group (—SO₃H), sulfinic acid group (—SOOH), thiosulfonic acid group (—COSH), nitrate ester group (—ONO₂), nitrite ester group (—ONO), cyanate ester group (—OCN), isocyanate ester group (—NCO), phosphate ester group (—OPO(OH)₂), phosphite ester group (—PO(OH)₂), thiol group (—SH), primary amine group (—NH₂), secondary amine group (—NH), and tertiary amine group (—NR₂).

22. The quantum dot material according to claim 1, wherein the first type of ligand compound comprises at least two of the following: Oleic Acid (CAS NO: 112-80-1), Stearic acid (CAS NO: 57-11-4), 4-Dodecylbenzenesulfonic acid (CAS NO: 121-65-3), 1-Octadecanethiol (CAS NO: 2885-00-9), 2,2′-Iminodiethanol (CAS NO: 111-42-2), Methylammonium acetate (CAS NO: 6998-30-7), and (3-(1-Pyridinio)-1-propanesulfonate (CAS NO: 15471-17-7).

23. The quantum dot material according to claim 7, wherein the second type of ligand compound comprises at least one of the following: (3-Aminopropyl triethoxysilane (APTES; CAS NO: 919-30-2), 3-Aminopropyl trimethoxysilane (APTMS; CAS NO: 13822-56-5), (3-Mercaptopropyl) triethoxysilane (MPTES; CAS NO: 14814-09-6), 3-Mercaptopropyl trimethoxysilane (MPTMS; CAS No. 4420-74-0), Cysteine (CAS No. 52-90-4), 3-Sulfanylpropanoic acid (CAS No. 107-96-0), ethanolate; titanium (4+) (CAS No: 3087-36-3), Titanium isopropoxide (CAS No: 546-68-9), Titanium tetrachloride (CAS No: 7550-45-0), Trimethylalane (CAS No: 75-24-1), and Zirconyl nitrate (CAS No: 13826-66-9).

24. The quantum dot material according to claim 1, wherein a main chain length of the first-type ligand compound has a carbon number greater than or equal to 10.

25. A method for preparing a quantum dot material, comprising the following steps of:
mixing a formamidinium ion precursor, a lead ion precursor, and a ligand in a solvent to form a mixed solution;
drying the mixed solution at a first temperature;
cooling the dried mixed solution to a second temperature lower than the first temperature in an inert gas environment; and
injecting a bromide ion precursor into the mixed solution at the second temperature to generate a solution containing the quantum dot material.
wherein the generated quantum dot material has a crystal structure of ABX₃, with A sites occupied by formamidinium ions, B sites occupied by lead ions, and X sites occupied by bromide ions, and
wherein the generated quantum dot material, when a wavelength of the incident light is 450 nm, has a maximum emission wavelength ranging from 525 nm to 535 nm in response to the incident light.

26. The method for preparing a quantum dot material according to claim 25, wherein the ligand comprises oleic acid and sulfobetaine.

27. The method for preparing a quantum dot material according to claim 26, wherein the sulfobetaine comprises 3-(N,N-Dimethyloctylammonio)-propanesulfonate.

28. The method for preparing a quantum dot material according to claim 25, wherein the first temperature does not exceed 120° C.

29. The method for preparing a quantum dot material according to claim 28, wherein the first temperature is greater than or equal to 100° C., and the second temperature is between 40° C. and 75° C.

30. The method for preparing a quantum dot material according to claim 25, further comprising:
performing a first centrifugation process on the solution containing the quantum dot material to obtain a precipitate;
adding an organic solvent to the precipitate and performing a second centrifugation process; and
filtering the quantum dot material based on a supernatant after the second centrifugation process.

31. The method for preparing a quantum dot material according to claim 25, wherein the ligand comprises a first type of ligand compound and a second type of ligand compound, wherein
the first type of ligand compound has a chemical formula of ZRₙ_{₁}, where Z is the first coordinating group; and Rₙ_{₁} is a first alkane, and n₁ is a number of chains of the first alkane, which is greater than 0; and
the second type of ligand compound has a chemical formula of ZRₙ_{₂}K_{X}, where Rₙ_{₂} is a second alkane, n₂ is a number of chains of the second alkane, which is greater than or equal to 0, and K_{X} is the second coordinating group.

32. The method for preparing the quantum dot material according to claim 31, wherein the second type of ligand compound further comprises: second functional groups, so that the chemical formula of the second type of ligand compound is: ZRₙ_{₂}K_{X}Wₘ₂, where W_{M2} is the second functional group, and m2 is a number of the second functional groups, which is a positive integer.

33. The method for preparing the quantum dot material according to claim 32, wherein
the first coordinating group is selected from any one of the following: carboxyl group (—COOH), sulfonic acid group (—SO₃H), sulfinic acid group (—SOOH), thiosulfonic acid group (—COSH), nitrate ester group (—ONO₂), nitrite ester group (—ONO), cyanate ester group (—OCN), isocyanate ester group (—NCO), phosphate ester group (—OPO(OH)₂), phosphite ester group (—PO(OH)₂), thiol group (—SH), primary amine group (—NH₂), secondary amine group (—NH), and tertiary amine group (—NR₂); and
the first functional group and the second functional group are selected from any one of the following: methyl group (—CH₃), ethyl group (—C₂H₆), propyl group (—C₃H₇), butyl group (—C₄H₉), pentyl group (—C₅H₁₁), hydroxyl group (—OH), amino group (—NH₃), and pyridyl group (—C₅H₅N).

34. A quantum dot film applicable for a backlight module, comprising the quantum dot material according to claim 1.

35. A backlight module, comprising the quantum dot film according to claim 34.
